(19) United States
(12) Patent Application Publication
(10) Pub. No.: US 2026/0177597 A1
(43) Pub. Date: Jun. 25, 2026

(54) Radio frequency interference resilient passive microwave sensor

(71) Applicant: Boulder Environmental Sciences and Technology, Boulder, CO (US)

(72) Inventor: Marian Klein, Boulder, CO (US)

(73) Assignee: Boulder Environmental Sciences and Technology, Boulder, CO (US)

(21) Appl. No.: 18/988,641

(22) Filed: Dec. 19, 2024

(51) Int. Cl. G01R 29/08

(52) U.S. Cl. CPC G01R 29/0878

(57) ABSTRACT

A microwave radiometer sensor that reduces observational noise and enables observations in the presence of interference is disclosed. Microwave radiometers provide very valuable environmental observations from space. Their observations, however, are threatened by anthropogenic signals, radio frequency interference (RFI), that are emitted by communication systems, automobile and various other radars, and other emitting sources. This invention describes a method of RFI detection that is simple, can be highly integrated into a compact, low weight, and minimal power consuming technology. The solution is economical, provides increased observational sensitivity, and makes environmental observations more sensitive and more reliable even in the presence of a certain level of interference.

### REFERENCES CITED

### U.S. Patent Documents

US 2011/0292988 A1: Classification of interference, Inventor: Wieslaw Jerzy Szajnowski.
U.S. Pat. No. 10,917,178B2, “Frequency agile microwave radiometer, hyperspectral microwave radiometer and methods of operation”, Tom Dillon, Newark, DE (US); Christopher Schuetz, Avondale, PA (US); Dennis Prather, New Castle, DE (US)

### Other Publications

Aires, F., C. Prigent, E. Orlandi, M. Milz, P. Eriksson, S. Crewell, C. Lin, and V. Kangas. 2015. “Microwave hyperspectral measurements for temperature and humidity atmospheric profiling from satellite: The clear-sky case.” Journal of Geophysical Research—Atmospheres (American Geophysical Union) 120 (21): 11,334-11,351. doi:10.1002/2015JD023331.
Bauer, P., and A. Mugnai. 2003. “Precipitation profile retrievals using temperature-sounding microwave observations.” Journal of Geophysical Research 108 (D23): 4730-4743. doi:10.1029/2003JD003572.
Blackwell, W. J., L. J. Bickmeier, R. V. Leslie, M. L. Pieper, J. E. Samra, C. Surussavadee, and C. A. Upham. 2011. “Hyperspectral Microwave Atmospheric Sounding.” IEEE Transaction on Geoscience and Remote Sensing 128-142. doi:10.1109/TGRS.2010.2052260.
Boukabara, S. A., and K. Garrett. 2011. “Benefits of a Hyperspectral Microwave Sensor.” 2011 IEEE Sensors. Limerick, Ireland: IEEE. 1881-1884.
Draper, D. W. 2018. “Radio Frequency Environment for Earth-Observing Passive Microwave Imagers.” IEEE JOURNAL OF SELECTED TOPICS IN APPLIED EARTH OBSERVATIONS AND REMOTE SENSING 1913-1922. doi:10.1109/JSTARS.2018.2801019.

English, S., T. McNally, N. Bormann, K. Salonen, M. Matricardi, A. Horanyi, M. Rennie, et al. 2013. Impact of satellite data. Technical memorandum, Reading, England: ECMWF.
Kummerow, C. D., J. C. Poczatek, S. Almond, W. Berg, 0. Jarrett, A. Jones, M. Kantner, and C. P. Kuo. 2022. “Hyperspectral Microwave Sensors-Advantages and Limitations.” IEEE Journal of Selected Topics in Applied Earth Observation and Remote Sensing 764-775. doi:10.1109/JSTARS.2021.3133382.
Lupu, C. 2019. “Data assimilation diagnostics: Assessing the observations impact in the forecast.” ECMWF Data assimilation training course 51.
Piepmeier, J. R., P. N. Mohammed, G. DeAmici, E. Kim, J. Peng, and C. Ruf. 2016. Soil Moisture Active Passive (SMAP) Project, Algorithm Theoretical Basis Document, SMAP L1B Radiometer Brightness Temperature, Data Product: L1B_TB (Rev. B). NASA Goddard Space Flight Center.
Piepmeier, J. R., J. T. Johnson, P. N. Mohammed, D. Bradley, C. Ruf, M. Aksoy, R. Garcia, D. Hudson, L. Miles, and M. Wong. 2014. “Radio-frequency Interference Mitigation for the Soil Moisture Active Passive Microwave Radiometer.” IEEE Transaction on Geoscience and Remote Sensing 761-775. doi: 10.1109/TGRS.2013.2281266.

### FIELD OF INVENTION

This invention relates generally to systems for remote sensing and, more specifically, to systems implementing passive microwave remote sensing, also known as radiometers, or radiometry. The invention is related to improving observations in general, and also in the presence of radio frequency interference—RFI.

### BACKGROUND OF THE INVENTION

Passive microwave sensors from orbit provide the most valuable information about the climate, the water and energy cycles, and for weather forecasting models, as described by e.g., English, S., T. McNally, N. Bormann, K. Salonen, M. Matricardi, A. Horanyi, M. Rennie, et al. 2013, “Impact of satellite data.” Technical memorandum, Reading, England, ECMWF; and Lupu, C. 2019 “Data assimilation diagnostics: Assessing the observations impact in the forecast” ECMWF Data assimilation training course 51; and many others. These sensors have a lot more to offer if their spatial, temporal, and spectral resolution can be improved. Their observations, however, are threatened by manmade signals, Radio Frequency Interference (RFI). RFI is a unique problem for the sensors operating within the microwave spectrum, where RFI contamination reduces the capabilities of active (radars) and passive sensors (radiometers) used for environmental observations.

There are numerous solutions for detecting the interference within a channel, or within a narrow bandwidth (e.g., up to tens of GHz). Such algorithms are currently used for the Soil Moisture Active Passive (SMAP) microwave radiometer, as described by, e.g., Piepmeier, J. R., P. N. Mohammed, G. DeAmici, E. Kim, J. Peng, and C. Ruf. 2016, “Soil Moisture Active Passive (SMAP) Project, Algorithm Theoretical Basis Document, SMAP L1B Radiometer Brightness Temperature, Data Product: L1B_TB (Rev. B)”, NASA Goddard Space Flight Center; and Piepmeier, J. R., J. T. Johnson, P. N. Mohammed, D. Bradley, C. Ruf, M. Aksoy, R. Garcia, D. Hudson, L. Miles, and M. Wong. 2014, “Radio-frequency Interference Mitigation for the Soil Moisture Active Passive Microwave Radiometer.” IEEE Transaction on Geoscience and Remote Sensing 761-775. doi: 10.1109/TGRS.2013.2281266. Many other papers describe applications of such algorithms to future sensors, e.g., Kummerow, C. D., J. C. Poczatek, S. Almond, W. Berg, 0. Jarrett, A. Jones, M. Kantner, and C. P. Kuo, 2022, “Hyperspectral Microwave Sensors—Advantages and Limitations.” IEEE Journal of Selected Topics in Applied Earth Observation and Remote Sensing 764-775. doi:10.1109/JSTARS.2021.3133382; and the patent US 2011/0292988 A1: Classification of interference, Inventor: Wieslaw Jerzy Szajnowski.

A good review of various state-of-the-art methods is presented in: S. Misra et al., “Microwave Radiometer Radio-Frequency Interference Detection Algorithms: A Comparative Study.” IEEE Transaction on Geoscience and Remote Sensing, pp. 3742-3754, November 2009.

These solutions provide detection within a relatively narrow radiometer band by digitizing the channel output and an application of sophisticated digital filtering algorithms in order to detect an interfering signal. While important, this approach is also very power hungry and bulky. The amount of generated data generally does not allow for download from space-based sensors. Thus, the data processing is usually done onboard the satellite. Dividing already a narrow radiometer band to sub-bands reduces radiometer sensitivity, or NEDT (Noise Equivalent Delta Temperature). The radiometer sensitivity is a major technical characteristic of a passive sensor and determines the level of noise in the observations. For example, if a bandwidth of the sensor channel is divided to 16 sub-bands for RFI detection, the NEDT increases four times. Similarly, for 64, 256 sub-bands corresponding increase in NEDT is 8 or 16 times respectively. That is a significant loss of the radiometer sensitivity. Since no RFI can be detected below the NEDT level of the instrument, the detection capabilities of such technological solution are diminishing with increased number of sub-bands.

### SUMMARY OF THE INVENTION

The disclosed invention maximizes the observational capabilities of passive microwave systems, radiometers, reduces their observational noise, and allows detection of the RFI presence in the observed data.

The invention disclosed here is a method or RFI detection that uses a multichannel (hyperspectral) radiometer that is monitoring a majority, or all of the available spectrum for passive observations. The method does not need to use digitization, and it is much simpler than current methods for RFI detection. It doesn't consume excessive amounts of power, and it can be integrated into a compact, economic, low power package. In addition to RFI detection, such hyperspectral solution improves observations with respect to the current state of the art, as documented in literature by many authors, including Boukabara, S. A., and K. Garrett. 2011, “Benefits of a Hyperspectral Microwave Sensor” 2011 IEEE Sensors. Limerick, Ireland: IEEE 1881-1884; and Maddy, E. S., F. Iturbide-Sanches, S. A. Boukabara, 2024, “Toward the Next Generation of Microwave Sounders: Benefits of a Low-Earth Orbit Hyperspectral Microwave Instrument in All-Weather Conditions Using AI”, IEEE Journal of selected topics in applied Earth observations and remote sensing, Vol. 17, 2024, DOI: 10.1109/JSTARS.2024.3356858. The disclosed class of hyperspectral sensors is an economical solution, that is efficient, and it is mostly built on already existing technology.

Until recently, the RFI was mostly encountered in the lower frequency band, below ˜20 GHz, as described by, e.g., Draper, D. W. 2018, “Radio Frequency Environment for Earth-Observing Passive Microwave Imagers.” IEEE Journal of selected topics in applied earth observations and remote sensing 1913-1922. doi:10.1109/JSTARS.2018.2801019. Currently, the spectrum allocation allows operation of active transmitters at higher frequencies, operating around 24 GHz. The 57-64 GHz band within the oxygen absorption band is unlicensed.

It can be presumed that the interference sources are relatively narrow in frequency domain, and interference is somehow a geographically localized phenomenon. For example, the Starlink channels that use frequencies from 47.2-50.2, and 50.4-51.4 GHz to send information from the gateways back up to the satellites. Thus, there might be some geographical distribution of these interfering signals and there might be spatial and temporal gaps where the RFI signal levels will be negligible and will permit environmental observations.

There are, however, areas of interference spread over wide geographic regions, including over oceans, as described by Draper, D. W. 2018. “Radio Frequency Environment for Earth-Observing Passive Microwave Imagers.” IEEE JOURNAL OF SELECTED TOPICS IN APPLIED EARTH OBSERVATIONS AND REMOTE SENSING 1913-1922. doi:10.1109/JSTARS.2018.2801019.

### BRIEF DESCRIPTION OF THE DRAWINGS

The present disclosure will now be descried more fully with reference to the accompanying drawings, in which various embodiments are shown.

FIG. 1 is a plot of relative sensitivity of passive microwave sensors to various Earth surface and atmospheric parameters between 1 and 100 GHz.

FIG. 2 shows atmospheric opacity for the spectrum from 5 to 220 GHz. Shaded rectangles show potential channel distribution of a multichannel/hyperspectral microwave sensor.

FIG. 3 shows atmospheric opacity for the spectrum from 49 to 73 GHz. Shaded rectangles show potential distribution of 31 channels of a multichannel/hyperspectral microwave sensor.

FIG. 4 shows atmospheric opacity for spectrum between 5 and 220 GHz. Shaded rectangles show potential channel distribution of a multichannel/hyperspectral microwave sensor. Black rectangles show parts of the spectrum reserved for passive sensors only.

FIG. 5 shows atmospheric opacity for spectrum between 5 and 220 GHz. Shaded rectangles show potential channel distribution of a multichannel/hyperspectral microwave sensor. Black rectangles show allocation of channels of the AMSR2 microwave sensor.

FIG. 6 shows atmospheric opacity for spectrum between 5 and 220 GHz. Shaded rectangles show potential channel distribution of a multichannel/hyperspectral microwave sensor. Black rectangles show allocation of channels of the Weather System Follow-on Microwave sensor.

FIG. 7 shows atmospheric opacity for spectrum between 5 and 220 GHz. Shaded rectangles show potential channel distribution of a multichannel/hyperspectral microwave sensor. Black rectangles show allocation of channels of the Advanced Technology Microwave Sounder sensor.

For simplicity and clarity of illustration, the drawing figures illustrate the general method, and descriptions and details of well-known features and techniques. Some details may be omitted to avoid unnecessarily obscuring the invention. The same reference numerals in different figures denote the same elements.

### DETAILED DESCRIPTION

The present disclosure now will be described more fully hereinafter with reference to the accompanying drawings, which various exemplary embodiments are illustrated. The invention may, however, be embodied in many different forms and should not be construed as limited to the exemplary embodiments set forth herein. These example exemplary embodiments are just that—examples—and many embodiments and variations are possible that do not require the details provided herein. It should also be emphasized that the disclosure provides details of alternative examples, but such listing of alternatives is not exhaustive. Furthermore, any consistency of detail between various exemplary embodiments should not be interpreted as requiring such detail—it is impracticable to list every possible variation for every feature described herein. The language of the claims should be referenced in determining the requirements of the invention.

Ordinal numbers such as “first,” “second,” “third,” etc. may be used simply as labels of certain elements, steps, etc. to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim). As used herein, the term “and/or” includes any and all combinations of one or more of the associated listed items.

Unless otherwise defined, all terms (including technical and scientific terms) used herein have the same meaning as commonly understood by one of ordinary skill in the art of this disclosure. It will be further understood that terms, such as those defined in commonly used dictionaries, should be interpreted as having a meaning that is consistent with their meaning in the context of the relevant art and will not be interpreted in an idealized or overly formal sense unless expressly so defined herein. Hereinafter, example embodiments will be explained in detail with reference to the accompanying drawings. The same reference numerals will be used to refer to the same elements throughout the drawings and detailed description about the same elements may be omitted in order to avoid redundancy.

As the world population density increases and our economies dependence on weather intelligence grows, the importance of weather observations is also increasing. Passive microwave sensors from Low Earth Orbit (LEO) significantly contribute to the accuracy of weather forecasts. The same microwave spectrum is also used for communication devices, such as 5G mobile phones, communication to and from satellites (e.g., Starlink), microwave towers intercommunication, vehicle, weather, aviation radars, and many other applications. Thus, the RFI interference is growing at the time of a need for more accurate weather observations.

A defense against this RFI trend presented in this invention is to observe across the maximum of the available spectrum, take redundant observations, and use nature contiguous properties to determine RFI contamination. Since the number of RFI sources is likely to increase in the future, the strategy of maximizing spectral coverage of observations is likely the most robust approach to efficient observations in the future.

The goal of the concept presented in this invention is to enable continuation of the weather satellites environmental observation, and even improve them, by a use of hyperspectral sensors operating in a contested microwave frequency spectrum.

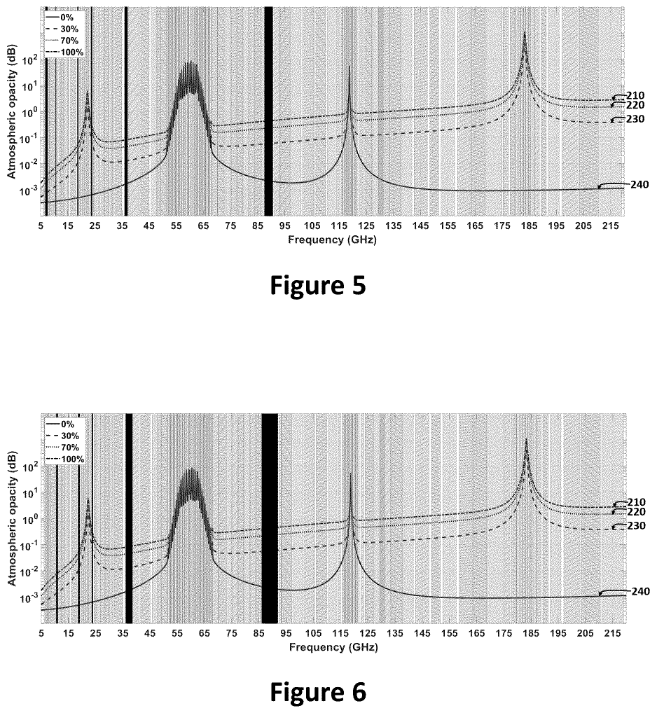

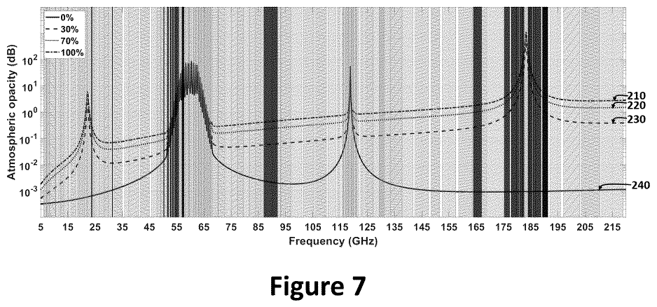

An obvious conclusion from FIG. 5, FIG. 6, and FIG. 7 is that there is a lot of spectra that is currently not being used for environmental monitoring. Black rectangles are showing where observations are taken by the current satellite instruments.

Since only narrow portions of the spectrum are used for observations, any emitters that are located in these parts of the spectrum, or in the vicinity and emitting into some channels, can potentially ruin observations over a region, for example, at a particular location, or over a geographically larger area, e.g., a reflected signal of a communication satellite transmitter from an ocean surface. Finding and identifying emission sources is difficult in general, and preventing them from continuing their operations is even more challenging, or impractical.

When only a narrow frequency band is used for observations, such as shown on FIG. 5, FIG. 6, and FIG. 7, then the RFI detection technologies are limited to using the frequency range within a particular channel only.

A critical parameter of microwave radiometers on orbit is their sensitivity. The radiometric sensitivity, sometimes also called noise equivalent differential temperature (NEDT), is a very important parameter of the sensor, since it determines precision of the observations of the sensor, and how much observational noise is found in the data. A reduction of observational noise leads to higher quality of data.

The radiometric sensitivity of a passive microwave sensor ΔT, or NEDT, is defined as

$$Δ T = \frac{{T}_{SYS}}{\sqrt{B \cdot τ}}$$

Where T_{SYS} is system temperature, t is the integration time, and B is a channel bandwidth. In practice the T_{SYS} is determined by the current status of the technology. In recent designs the noise figure of the input low noise amplifiers determines the system temperature almost completely. When a sensor is scanning on orbit and makes observations its integration time, t, is determined by the sensor orbit, its spatial resolution on the ground, scanning geometry, observational goals, and other parameters. Usually, the t is in order of a few milliseconds, e.g., 2-20 milliseconds, and it cannot be increased substantially. Opposite, the technology is moving towards sensors with improved spatial resolution and integration time is thus significantly shortened. The bandwidth of the sensors currently on orbit vary from a few megahertz (MHz) to a couple of gigahertz (GHz) per channel.

Traditionally, the sensors overall bandwidth and individual channel center frequency and bandwidths are determined by potential users, their requirements on performance, and also by sensor designers, economy requirements on the sensor design, available technology, or chosen technology for the sensor, and other factors.

One way to understand the NEDT formula is that it is a minimal amount of energy (here expressed as ΔT) a radiometer can observe must be higher than its own noise power, determined by the formula. T_{SYS} is essentially the sensor noise power. More energy can be delivered to a sensor, if its bandwidth B or integration time t, or both, are increased (and other parameters of the sensor are not changed). If more energy enters the sensors, for example, over a wider bandwidth, the radiometer sensitivity is higher, leading to a lower observational noise. Increasing the number of channels, widening the sensor operational bandwidth, is thus a solution that lowers the observational noise.

Existing RFI detection systems use digital signal processing of over data available in a selected channel, e.g., one of the black rectangles on FIG. 5, FIG. 6, or FIG. 7. The available bandwidth is digitally sampled, and billions of mathematical operations are performed to filter multiple channels, e.g., 8, or 2,000, for interference detection by various methods, such as pulse or kurtosis detection algorithms (references cited in the “Description of the background” section). These are very sophisticated digital filtering and detection algorithms. However, performing billions of mathematical operations per second consumes a lot of power and produces a lot of data, and creates a very complicated system. It is estimated that current FPGA (field programmable gate array) used for such spectrometer approach requires ˜10 W/GHz. In addition, dividing the available bandwidth of a receiver to multiple channels with, e.g., 10 MHz or narrower bandwidths, increases observational noise significantly and that reduces the sensitivity of the sensor.

There are emerging technologies, such as microwave photonic instrument described by, e.g., A. Gambacorta et al., “Advancing Atmospheric Thermodynamic Sounding From Space Using Hyperspectral Microwave Measurements,” in IEEE Journal of Selected Topics in Applied Earth Observations and Remote Sensing, vol. 16, pp. 5204-5218, 2023, doi: 10.1109/JSTARS.2023.3269697, the U.S. Pat. No. 10,917,178B2, “Frequency agile microwave radiometer, hyperspectral microwave radiometer and methods of operation”, and others. These are hyperspectral sensors and improve observational capabilities too. This is an emerging technology and there is at least a decade before these systems solve their technological challenges and only then we will understand how practical is their solution.

This invention proposes to use a different approach. That is using of as wide spectrum as feasible, or all of it, for passive observations. An example of such approach is illustrated on FIG. 2 through FIG. 7. Since microwave sensors are passive, there is no need for a Federal Communication Commission (FCC) permission for operations. Using maximum of available spectrum reduces the observational noise and it provides a very effective method for detection of channels where the interference is present. In addition, multiple and redundant channels, i.e. using hyperspectral microwave sensors, improves environmental observations, if not interfered with.

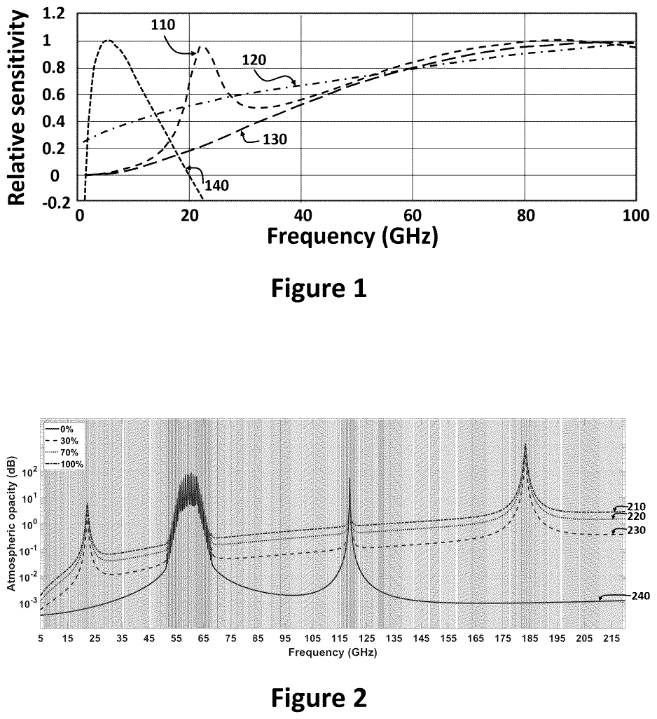

The RFI, the man-made signals, usually have preferential polarization, for example, horizontal, vertical, or circular. Thus, a microwave radiometer sensor observing nature in multiple polarizations will improve the RFI detection probability. There are very few natural phenomena that produce polarization signals (a different level of observed energy, i.e., brightness temperature in two polarizations, vertical, horizontal). Such phenomena are, for example, ocean surface roughness caused by wind, aligned non-spherical precipitation particles, and others. These phenomena are known, their polarization variations are expected, and they will be observed over a wider frequency range than an RFI source bandwidth. Natural phenomena signal is broadband, and follows a smooth curve. Radiation from a natural source is a continuous curve that has no breaks, sharp corners, or cusps, as shown on FIG. 1.

Examples of wide frequency spectrum and multiple channels concept are illustrated on FIG. 2 through FIG. 7. This approach provides benefits of a hyperspectral microwave sensor. These benefits have been investigated by numerous authors, for example, Aires, F., C. Prigent, E. Orlandi, M. Milz, P. Eriksson, S. Crewell, C. Lin, and V. Kangas, 2015, “Microwave hyperspectral measurements for temperature and humidity atmospheric profiling from satellite: The clear-sky case.” Journal of Geophysical Research—Atmospheres (American Geophysical Union) 120 (21): 11,334-11,351. doi:10.1002/2015JD023331; or Blackwell, W. J., L. J. Bickmeier, R. V. Leslie, M. L. Pieper, J. E. Samra, C. Surussavadee, and C. A. Upham, 2011, “Hyperspectral Microwave Atmospheric Sounding.” IEEE Transaction on Geoscience and Remote Sensing 128-142, doi:10.1109/TGRS.2010.2052260, or Maddy, E. S., F. Iturbide-Sanches, S. A. Boukabara: Toward the Next Generation of Microwave Sounders: Benefits of a Low-Earth Orbit Hyperspectral Microwave Instrument in All-Weather Conditions Using AI, IEEE Journal of selected topics in applied Earth observations and remote sensing, Vol. 17, 2024 DOI: 10.1109/JSTARS.2024.3356858, and many others.

An example of channels of such hyperspectral sensor is on FIG. 2. The sensor has 114 channels. Assuming that two polarizations are used, e.g., vertical and horizontal polarization, then the total number of channels is 228. This is an illustration only where the narrow bandwidth channels are selected in the vicinity of the absorption lines and wider bandwidth is used in the atmospheric windows. The plot is for analog filters of several radiometers. This, however, does not imply that it is the only or the best solution. This solution is simple, energy efficient, and can be realized with currently existing technology.

In this invention the channels are selected to provide as wide spectrum coverage as practical and any available technology can be used for channel selection. There is no channel optimization as, for example described in Maddy et al. 2024, or Aires et al. 2015 (referenced above), thus, there is a significant level of redundant information in observations. This redundancy is very beneficial, it reduces observational noise, and it benefits interference detection.

The naturally emitted radiation, caused by various natural phenomena, has a smooth characteristic over a frequency range. This is illustrated on FIG. 1. The FIG. 2 also shows smooth curves in response to atmospheric gasses, namely oxygen and water vapor, attenuation. The exceptions to smooth curvature are in the center of an absorption line of any atmospheric gas. There the continuity of a curve derivatives is broken. The frequencies of these absorption lines are very well known and defined; thus, the discontinuities are expected. Everywhere else in the microwave spectrum, the adjacent channels of a radiometer, or even more distant channels responding to the same natural phenomenon, such as atmospheric temperature, ocean surface wind vector, cloud liquid, precipitation, and others, are highly correlated. This correlation will be broken when an interfering signal is added to a naturally emitted energy. The RFI is always stronger than the natural signal.

The data with multiple redundancies, observed by these sensors could be processes by any available or new mathematical algorithms, or artificial intelligence algorithms to evaluate the presence or absence of interference.

The foregoing description of embodiments of the invention has been presented for the purpose of illustration and description. It is not intended to be exhaustive or to limit the invention to the precise form disclosed. In light of the foregoing description, it is evident that many alterations, modifications, and variations will enable those skilled in the art to utilize the invention in various embodiments suited to the particular use contemplated.

### DETAILED DESCRIPTION OF THE DRAWINGS

FIG. 1 is a plot of relative sensitivity of a passive microwave sensor on orbit to various Earth surface and atmospheric parameters between 1 and 100 GHz. Earth surface parameters are observable within this frequency spectrum where the atmosphere is transparent enough. The line 110 shows sensitivity to integrated water vapor, line 120 sea surface wind speed, line 130 integrated cloud liquid water, and line 140 is a plot of sensitivity to sea surface temperature. There are many more parameters of a surface and the atmosphere that can be observed over this part of the spectrum, from 1 to ˜100 GHz. The FIG. 1 shows that all of the natural phenomena have a smooth characteristic with respect to frequency. An RFI interference usually occurs in a narrow band and it would cause an unnatural rise of the observed brightness temperature in the part of the spectrum affected. Above a certain level of intensity, a multichannel microwave radiometer sensor, as described in this invention, would be able to detect it.

FIG. 2 shows atmospheric opacity for the spectrum from 5 to 220 GHz. Shaded rectangles show potential channel distribution of a hyperspectral microwave sensor. Total number of channels of the hyperspectral sensor on the FIG. 2 is 114. The atmospheric opacity is the total attenuation of the atmospheric column at a given frequency plotted for the US Standard Atmosphere with added relative humidity of 100%—line 210, for 70%—line 220, for 30%—line 230, and for no humidity, thus relative humidity of 0% is line 240. The channels are selected such that each is technically feasible, not very narrow or too wide. The narrowest bandwidths are close to the atmospheric absorption lines, and wider bandwidth in the atmospheric windows. The observations in the spectrum are redundant. The redundancy enables interference detection and reduces observational noise.

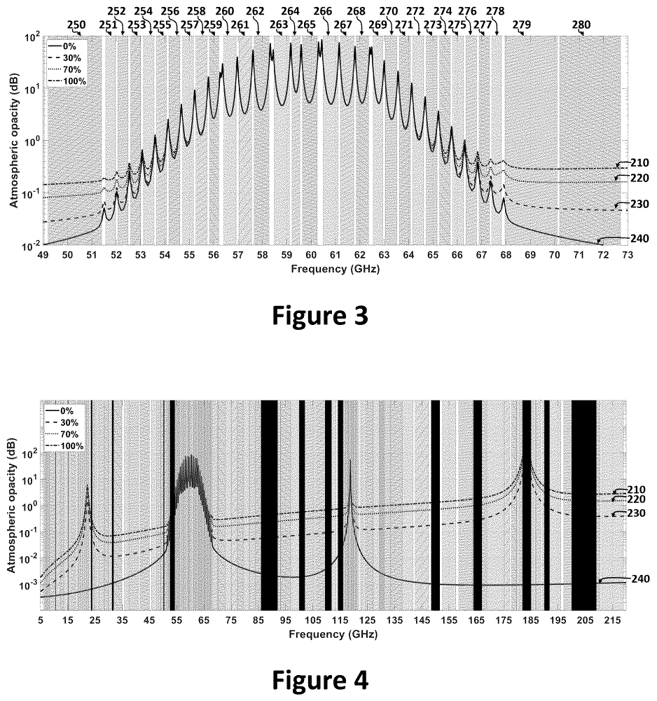

A potential distribution of a hyperspectral channels in the oxygen absorption spectra between 49 and 73 GHz is on FIG. 3. The lines are plotted for the US Standard Atmosphere with added relative humidity of 100%—line 210, for 70%—line 220, for 30%—line 230, and for no humidity, thus relative humidity of 0% is line 240. Shaded rectangles show potential distribution of 31 channels of a hyperspectral sensor. These individual channels are numbered starting with 250 and ending with channel number 280. Channel distribution is using practically all available spectrum the nature offers. As an example, each channel uses spectrum between two adjacent oxygen absorption lines. In this selection, the peaks are avoided, since the peak attenuation depends not only on atmospheric temperature but also on strength of the geomagnetic field of the Earth, as a consequence of the Zeeman effect. The hyperspectral sensor uses maximum of the spectrum available, to provide redundant information and reduce the observational noise.

Only a part of this spectrum is protected, as shown on FIG. 4. The two protected frequency bands exist within this portion of the spectrum, 50.2-50.4, and 52.6-54.4 GHz. Within this part of the spectrum are allocated active Starlink bands, 47.20-50.20, 50.40-51.40 GHz, and the unlicensed band 57-64 GHz. Thus, these are bands, where the RFI is likely.

Using a wide spectrum and multiple channels minimizes the observational noise, provides redundancy and enables finding channels that are clear of interference. In addition to RFI detection, redundancy of observations could provide better insights into the cloud composition, precipitation vertical distribution, (Bauer and Mugnai 2003), and improve observations of other atmospheric and surface phenomena within this spectral range.

Any microwave sensor can observe in multiple polarizations, for example, in horizontal and vertical, for additional redundancy and increased probability of RFI detection.

Parts of the spectrum between 6 and 220 GHz that are exclusively reserved for passive applications only are shown in black rectangles on FIG. 4. The atmospheric opacity is for the US Standard Atmosphere plotted for relative humidity of 100%—line 210, for 70%—line 220, for 30%—line 230, and for no humidity, thus relative humidity of 0% is line 240. As can be seen, very little of the spectrum has been reserved for observations of nature. Shaded rectangles show potential channel distribution of a hyperspectral microwave sensor.

FIG. 5 is a plot for the atmospheric opacity of the US Standard Atmosphere with added relative humidity of 100%—line 210, for 70%—line 220, for 30%—line 230, and for no humidity, thus relative humidity of 0% is line 240. Shaded rectangles show potential channel distribution of a hyperspectral microwave sensor. Black rectangles are channels of an Advanced Microwave Scanning Radiometer 2. The Advanced Microwave Scanning Radiometer 2 operates in an imaging mode and it has many applications in both, atmospheric and surface parameters observations. As can be seen, only a very small part of the spectrum is used by the Advanced Microwave Scanning Radiometer 2. The Advanced Microwave Scanning Radiometer 2 observes in multiple polarizations.

FIG. 6 is a plot for the atmospheric opacity of the US Standard Atmosphere with added relative humidity of 100%—line 210, for 70%—line 220, for 30%—line 230, and for no humidity, thus relative humidity of 0% is line 240. Shaded rectangles show potential channel distribution of a hyperspectral microwave sensor. Black rectangles are channels of the Weather Systems Follow-on—Microwave sensor that observes in multiple polarizations. The Weather Systems Follow-on—Microwave operates in an imaging mode and it has many applications in both, atmospheric and surface parameters observations. This sensor observes in multiple polarizations. As can be seen, only a very small part of the spectrum is used by the Weather Systems Follow-on—Microwave.

FIG. 7 is a plot for the atmospheric opacity of the US Standard Atmosphere with added relative humidity of 100%—line 210, for 70%—line 220, for 30%—line 230, and for no humidity, thus relative humidity of 0% is line 240. Shaded rectangles show potential channel distribution of a hyperspectral microwave sensor. Black rectangles are channels of the Advanced Technology Microwave Sounder. The Advanced Technology Microwave Sounder works as a sounder (it scans in the cross-track mode). Its primary application is atmospheric profiling (sounding) and it uses only a single polarization in every channel. Only a very small part of the spectrum is used by the Advanced Technology Microwave Sounder.

What is claimed is:

1. A method of radio frequency interference (RFI) detection for passive microwave sensors that uses multiple, redundant, correlated channels for interference detection.

2. The method of the claim 1 that uses multiple polarizations to improve the probability of RFI signals detection while keeping the observational capabilities of passive microwave sensors at maximum.

3. A method of passive microwave remote sensing that uses wide frequency spectrum, or all of the available frequency spectrum for observations. Resulting redundancy in observations improves the observational noise, ads a capability of detecting RFI infected channels, and provides the highest likelihood of successful environmental observations in the contested frequency spectrum.
